(19) United States
(12) Patent Application Publication
(10) Pub. No.: US 2021/0062321 A1
(43) Pub. Date: Mar. 4, 2021

(54) MANUFACTURING METHOD OF WIRELESS COMMUNICATION ANTENNA

(71) Applicant: SHENZHEN ACCOMTECH COMMUNICATION ELECTRONICS CO., LTD., Shenzhen (CN)

(72) Inventors: Tienan GUO, Shenzhen, Guangdong (CN); Tielong GUO, Shenzhen, Guangdong (CN); Guanglin XU, Shenzhen, Guangdong (CN); Yonggang TAN, Shenzhen, Guangdong (CN)

(21) Appl. No.: 16/632,805

(22) PCT Filed: Apr. 19, 2019
(86) PCT No.: PCT/CN2019/083510

§ 371 Date: Jan. 21, 2020

(30) Foreign Application Priority Data
Aug. 27, 2018 (CN) 201810981597.0

(51) Int. Cl. C23C 14/24; H01Q 1/02; H01Q 1/36; C23C 14/14

(52) U.S. Cl. CPC C23C 14/24; C23C 14/14; H01Q 1/362; H01Q 1/02

(57) ABSTRACT

The present disclosure discloses a manufacturing method of a wireless communication antenna, including: step S10, forming a surface metal layer on one side surface of a flexible thin film; step S20, patterning the surface metal layer to form a spiral type antenna; and step S30, vacuum depositing a metal on the other side surface of the flexible thin film to form an inner surface metal layer. The present disclosure realizes heat dissipation for various components in a portable terminal while realizing a better near field wireless communication.

### TECHNICAL FIELD

The present disclosure relates to a manufacturing method of a wireless communication antenna, more particularly relates to a manufacturing method of a wireless communication antenna by using a surface metal layer preformed on one side surface of a flexible thin film and forming an inner surface metal layer on the other side surface of the flexible thin film in order to implement an additional function of a so-called heat dissipation patch or heat dissipation radiation patch. Since the inner surface metal layer is simply and easily formed through a manner of vacuum deposition, the metal wasted during the processing is reduced, an easy workability is ensured, and the productivity of the wireless communication antenna can be improved greatly.

### BACKGROUND ART

Generally speaking, a tablet computer or a smart phone generates heat due to driving of a plurality of circuit components required for wireless communication or various operations through power supply, and such the heat acting as a main factor for shortening the mutual life of the components, therefore, a structure that can dissipate heat as quickly as possible is required.

FIG. 1 is a diagram showing an embodiment of an antenna coil of the prior art document (No. 2016-0121073 of Published Patent Gazette of Republic of Korea).

The structure of a wireless antenna coil for a smart phone of the prior art document is as shown in FIG. 1, two wireless data receiving coils 51-1 and 51-2 capable of wirelessly receiving data are provided at an outer housing portion, and a wireless energy receiving coil 52 is provided inside the data receiving coils 51-1 and 51-2.

Moreover, generally speaking, the largest wireless data receiving coil 51-1 that is located at an outer side may be an NFC coil, but the wireless data receiving coil 51-1 located at an immediately inner side may be the NFC coil as needed.

FIGS. 2a-5b are diagrams showing embodiments of configuring methods of a multi-antenna coil in the prior art reference document.

FIGS. 2a-2d are diagrams of embodiments of conditions that a wireless energy receiving coil is provided with wireless data receiving coils at the inside and outside thereof.

FIG. 2a is a diagram of an embodiment of a condition that there are two wireless energy receiving coils 52-1 and 52-2, and there are also two wireless data receiving coils 51-1 and 51-2 provided outside the wireless energy receiving coils 52-1 and 52-2.

FIGS. 2b and 2c are diagrams of embodiments of conditions that there are two wireless energy receiving coils 52-1 and 52-2, and there is one wireless data receiving coil 51-1 or 51-2 provided outside the wireless energy receiving coils 52-1 and 52-2.

At this time, one wireless data receiving coil 51-1 or 51-2 may be an NFC coil and may also be another data communication coil capable of performing authentication or settlement.

On the other hand, FIG. 2d is a diagram of an embodiment when there is one wireless energy receiving coil 52-1. Moreover, even in the case where there is one wireless energy receiving coil 52-1, two wireless data receiving coils 51-1 and 51-2 may be provided outside the wireless energy receiving coil 52-1.

On the other hand, when there is one wireless energy receiving coil 52-1, it is possible that only one wireless data receiving coil 51-1 or 51-2 is provided at the outside of the wireless energy receiving coil 52-1. At this time, the one wireless data receiving coil 51-1 or 51-2 may be the NFC coil and may also be another data communication coil capable of performing authentication or settlement.

FIGS. 3a-3d are diagrams showing embodiments that wireless data receiving coils 51-1 and 51-2 are provided independent of the wireless energy receiving coil 52. At this time, only one of the wireless data receiving coils 51-1 and 51-2 may exist, and in addition, the size of the wireless data receiving coil 51-1 or 51-2 may be less than and similar to that of the wireless energy receiving coil 52.

FIGS. 4a and 4b are diagrams showing embodiments that one wireless data receiving coil 51-1 or 51-2 is provided outside the wireless energy receiving coil 52, and the other one wireless data receiving coil 51-1 or 51-2 is provided at another position.

At this time, the coil located outside the wireless energy receiving coil 52 may be the NFC coil and may also be another data communication coil capable of performing authentication or settlement.

FIGS. 5a and 5b are diagrams showing embodiments of a condition that wireless data receiving coils 51-1 and 51-2 are provided independent of the wireless energy receiving coil 52, and there are two wireless data receiving coils 51-1 and 51-2.

Moreover, one of the two wireless data receiving coils 51-1 and 51-2 is provided inside, and the other is provided outside. On the other hand, the wireless data receiving coil provided inside may be the NFC coil, and the wireless data receiving coil provide outside may be another data communication coil capable of performing authentication or settlement; on the contrary, it is also possible that the wireless data receiving coil provided outside is the NFC coil, and the wireless data receiving coil provided inside is another data communication coil capable of performing authentication or settlement.

FIG. 6 is a diagram showing other functional thin film layers provided on the wireless antenna coil.

As shown in FIG. 6, at an upper end of a thin film 55 provided with the wireless antenna coils 52 and 51, a thin film 56 on which ferrite layers (magnetic layers) 56a and 56b are formed is provided, and in addition, a thin film 57 on which a heat dissipation thin film layer is formed is provided thereon.

Moreover, types of the ferrite layer 56a located at a portion at which the wireless energy receiving coil is and the ferrite layer 56b located at a portion at which the wireless data receiving coil is are different from each other.

A ferrite sheet may also have an insulation effect, but is a sheet-form component provided to minimize the influence of the magnetic field between the coils or between the coils and components. Thus, the ferrite sheet is located between the coils and mobile phone components.

Thus, although in the case where a multi-antenna coil substrate 55 in the prior art document is attached to the rear of a smart phone case, the ferrite sheet is located uppermost, on the contrary, in the case where the multi-antenna coil substrate 55 is attached to smart phone components such as a battery and the like, the ferrite sheet is attached downmost.

As the ferrite sheet, a silicon steel sheet is used, but it may also be commercially available materials such as manganese, ferrite, permalloy, iron-cobalt magnetic alloy, metallic glass, iron powder and the like. In addition, as an absorber form, zinc and the like may be used.

The ferrite sheet is provided at a boundary region between the coils, thereby reducing the influence of the magnetic field between the wireless energy receiving coil and the wireless data receiving coil.

FIGS. 7a and 7b are diagrams showing embodiments of sectional structures of a ferrite thin film and a heat dissipation thin film.

In order to be equipped to a smart phone, it is important to make a thickness of each layer thinner, and FIG. 7 is a diagram showing an embodiment for thinning the thickness of each layer.

In FIGS. 7a and 7b, the heat dissipation layer is coated on the heat dissipation thin film 57 to form a heat dissipation layer 57a, and a heat conductive adhesive layer 57b is formed under the heat dissipation film 57 in order to be engaged with the other layers. Moreover, the ferrite sheet forms the ferrite layers 56a and 56b on the ferrite thin film 56. At this time, in order to thin the overall thickness, the ferrite layer is coated at about 20 to 100 μm. Moreover, a heat conductive adhesive layer 56c is formed under the ferrite film 56.

However, the structure of a wireless antenna coil of the prior art used in smart phones is composed of a structure of coating heat dissipating layer on the heat dissipating film 57 to form the heat dissipating layer 57a and forming the conductive adhesive layer 57b under the heat dissipating film 57 in order to bond other layers, thus, it may bring the problem that the entire thickness become thicker due to the thickness of the heat dissipating film 57.

### SUMMARY

In consideration of the defect existing in the prior art, the present disclosure provides the following solutions.

The present disclosure provides a manufacturing method of a wireless communication antenna, including: step S10, forming a surface metal layer on one side surface of a flexible thin film; step S20, patterning the surface metal layer to form a spiral type antenna; and step S30, vacuum depositing a metal on the other side surface of the flexible thin film to form an inner surface metal layer.

Alternatively, the inner surface metal layer of the step S30 is used as a heat dissipation patch.

Alternatively, in the step S30, an one-way open slit unidirectionally opened is formed when vacuum depositing the metal on the other side surface of the flexible thin film, such that the inner surface metal layer is divided into one side metal region and the other side metal region based on the one-way open slit, thereby the surface metal layer is used as a heat dissipation radiation patch.

Alternatively, the step S30 further includes forming an expansion slot connected to the one-way open slit when vacuum depositing the metal on the other side surface of the flexible thin film.

Alternatively, in the step S20, the spiral type antenna includes: an inner spiral type pattern having an inner start end and an inner tail end formed by performing spiral type patterning on the surface metal layer of the one side surface of the flexible thin film; and an outer spiral type pattern having an outer start end and an outer tail end formed by performing spiral type patterning on the surface metal layer on the surface of the flexible thin film at the peripheral of the inner spiral type pattern; and in the step S30, the inner tail end and the one side metal region, and the outer start end and the other side metal region are respectively connected up and down when vacuum depositing the metal on the other side surface of the flexible thin film, so that the inner spiral type pattern, the heat dissipation radiation patch and the outer spiral type pattern are spirally connected in sequence.

Alternatively, in the step S30, in a state that a plurality of via holes penetrating vertically the flexible thin film in the middle, the metal is vacuum deposited on the other side surface of the flexible thin film, such that the metal fills the plurality of via holes to realize the connection between the inner tail end and one side metal region, and between the outer start end and the other side metal region.

Alternatively, in the step S30, a plurality of via grooves are formed by removing part of the flexible thin film, the via grooves expose the inner tail end and the outer start end toward a downside direction, the metal is deposited on the other side surface of the flexible thin film in vacuum, such that the metal fills the via grooves to realize the connection between the inner tail end and one side metal region, and between the outer start end and the other side metal region.

Alternatively, the inner start end is used as a first terminal, and the outer end is used as a second terminal.

Alternatively, the first terminal includes: a first outward terminal formed by performing linear patterning on the surface metal layer of the one side surface of the flexible thin film; a via terminal formed in a manner of independently performing vacuum deposition on the inner surface metal layer on the other side surface of the flexible thin film; and a plurality of via holes respectively connecting the inner start end and the via terminal, and the via terminal and the first outward terminal up and down, so that the inner start end, the via terminal and the first outward terminal are connected in sequence.

Alternatively, the second terminal is implemented by continuously connecting the surface metal layer on one surface of the flexible thin film to the second outward terminal formed by patterning outwardly and linearly.

In order to prepare a spiral type antenna having impedance and resistance in accordance with the wireless communication antenna, a surface metal layer preformed on one side surface of the flexible thin film is used, and in order to realize an additional function of the so-called heat dissipation patch or heat dissipation radiation patch, an inner surface metal layer is formed on the other side surface of the flexible thin film, and the inner surface metal layer is simply and easily formed through a manner of vacuum deposition, which reduce the metal wasted during the processing, ensure the easy workability, and can improve an effect of productivity of the wireless communication antenna greatly.

The present disclosure has an effect of realizing the overall lightness, thinness, shortness and minimization of a tablet computer or a smart phone by making the inner surface metal layer as the heat dissipation patch that can dissipate the heat generated by various components in a portable terminal.

The present disclosure may fill the metal that is vacuum deposited on the other side surface of the flexible thin film in the plurality of via holes to realize the connection in a state that the flexible thin film is placed in the middle and the plurality of via holes penetrating vertically the flexible thin film are formed, and has an effect of eliminating an usual process of independently plating the via holes to ensure the productivity.

The present disclosure has an effect of omitting the usual process of independently plating the via holes to ensure the productivity by vacuum depositing the metal on the other side surface of the flexible thin film and allowing the metal to fill the plurality of via holes to realize the connection between the inner tail end and one side metal region, and between the outer start end and the other side metal region in a state that the plurality of via holes respectively penetrating vertically the flexible thin film in the middle are formed

The inner spiral type pattern, the heat dissipation/radiation metal layer and the outer spiral type pattern of the present disclosure are connected in sequence to be a spiral type to form the wireless communication antenna, such as an NFC, WPT, MST, or the like.

The present disclosure has an effect of not only forming the inner spiral type pattern and the outer spiral type pattern on one side surface of the flexible thin film as the spiral type wireless communication antenna, but also forming the spiral type wireless communication antenna that is wound through the number of the additional turns of the heat dissipation radiation patch on the other side surface of the flexible thin film, so that communication performance in a narrow space in the portable terminal and space utilization of the portable terminal are ensured. Furthermore, since the one side metal region, the other side metal region, the inner spiral type pattern and the outer spiral type pattern formed by the one-way open slit of the other side surface of the flexible thin film are connected to each other, the heat dissipation radiation pattern works as a radiating body, which dissipates the heat generated by various components in the portable terminal as the heat dissipation radiation patch while further maximizing the performance of near field wireless communication, so that the overall lightness, thinness, shortness and minimization of the tablet computer or smart phone can be realized even if an additional structure of laminated heat dissipation thin films is not used.

The present disclosure has an effect of making the metal be deposited inside the flexible thin film, ensuring the pathway of the magnetic field relatively more with the help of the heat dissipation radiation patch having the one-way open slit and the expansion slot formed due to the inner surface metal layer, and making the wireless communication antenna of the portable terminal be totally connected to form an induced current, thereby, for example, making it possible to charge the battery more efficiently, or to further improve the function as the NFC or MST to ensure the quality of near field wireless communication.

The present disclosure has an effect that the magnetic field connects the wireless communication antenna of the portable terminal through the expansion slot and the one-way open slit and forms the induced current, and at the same time, the battery can be charged, or near field wireless communication such as the NFC or MST can be realized.

The present disclosure has the effect of forming the spiral type wireless communication formed by connecting the inner spiral pattern, the heat dissipation/radiation metal layer and the outer spiral pattern in sequence, by using the surface metal layer of one side surface and the inner metal layer of the other side surface of the thin and soft flexible thin film. That is, spiral type wireless communication antenna is realized not only the inner spiral type pattern and the outer spiral type pattern of on the surfaces of the flexible thin film, but also by winding the number of the additional turns of the heat dissipation/radiation metal layer on the other side surface of the flexible thin film is realized, so that the performance of the near field wireless communication can be further maximized while making the heat dissipation/radiation metal layer as the radiating body. Moreover, as the heat dissipation/radiation metal layer, it dissipates the heat generated by various components in the portable terminal, which may realize high-quality communication, ensuring heat dissipation, and lightness, thinness, shortness and minimization of the portable terminal.

The present disclosure connects the inner start end, the via terminal and the first outward terminal in sequence through a plurality of via holes to ensure the number of turns of the inner spiral type pattern.

### BRIEF DESCRIPTION OF THE DRAWINGS

FIG. 1 is a diagram of an embodiment of an antenna coil of the prior art document.

FIGS. 2a-5b are diagrams of embodiments of configuring methods of multi-antenna coils in the prior art reference document;

FIG. 6 is a diagram of an embodiment of other functional thin film layers provided on the wireless antenna coil;

FIGS. 7a and 7b are diagrams of embodiments of sectional structures of a ferrite thin film and a heat dissipation thin film;

FIG. 8 is a process diagram of a manufacturing method of a wireless communication antenna of the present disclosure;

FIG. 9a is a cross-section diagram of a metal thin film;

FIG. 9b is a cross-section diagram for illustrating respective steps of a manufacturing method of a wireless communication antenna of a first embodiment of the present disclosure;

FIG. 9c is a cross-section diagram for illustrating respective steps of a manufacturing method of a wireless communication antenna according to a second embodiment of the present disclosure;

FIG. 10 is a exploded stereo diagram of a wireless communication antenna according to a second embodiment of the present disclosure; and

FIG. 11 is exploded stereo of a wireless communication antenna according to a second embodiment of the present disclosure viewed from the back.

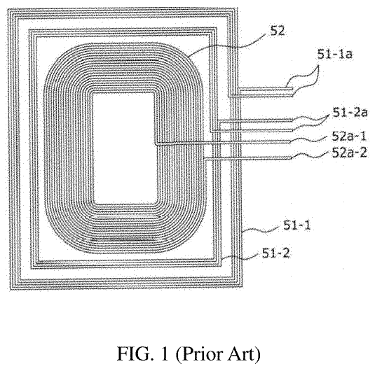

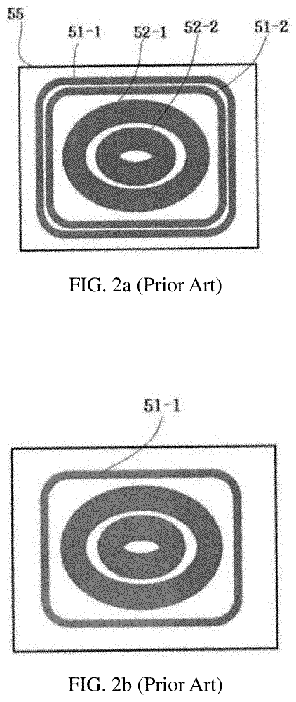

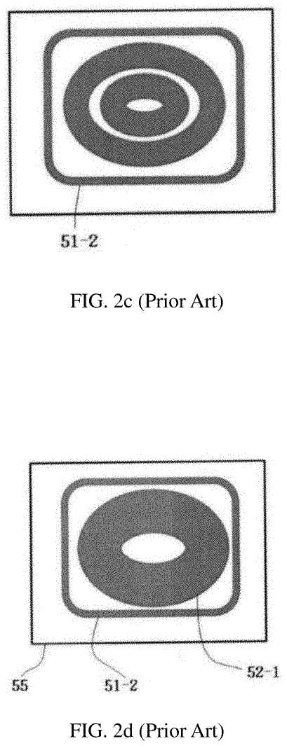

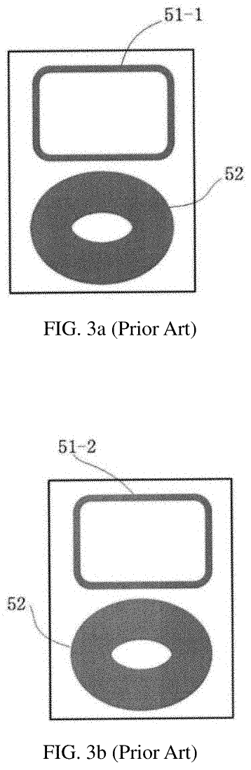

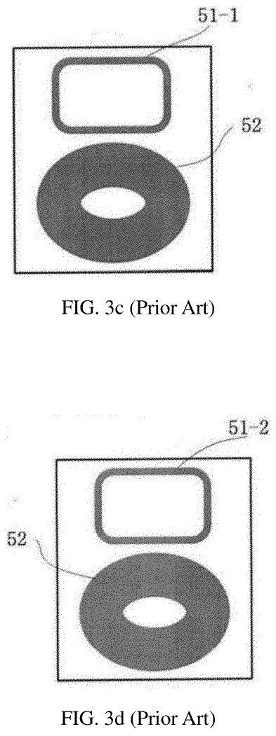

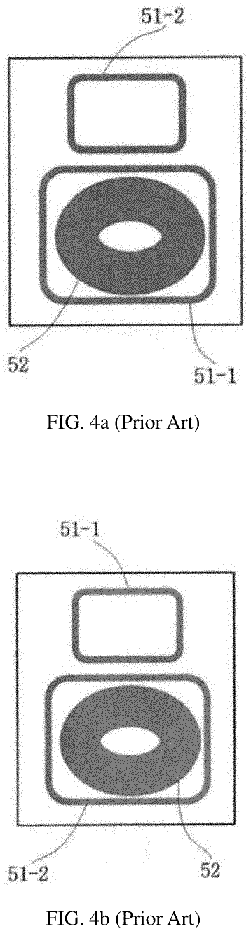

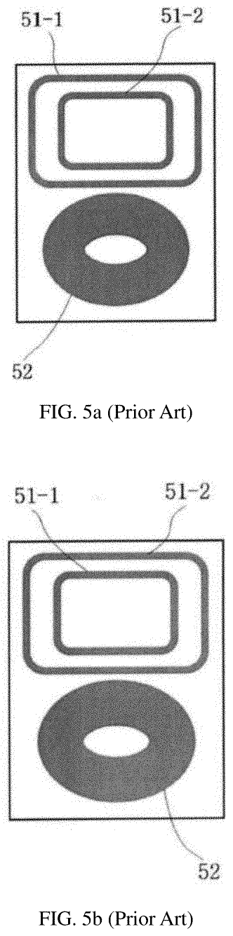

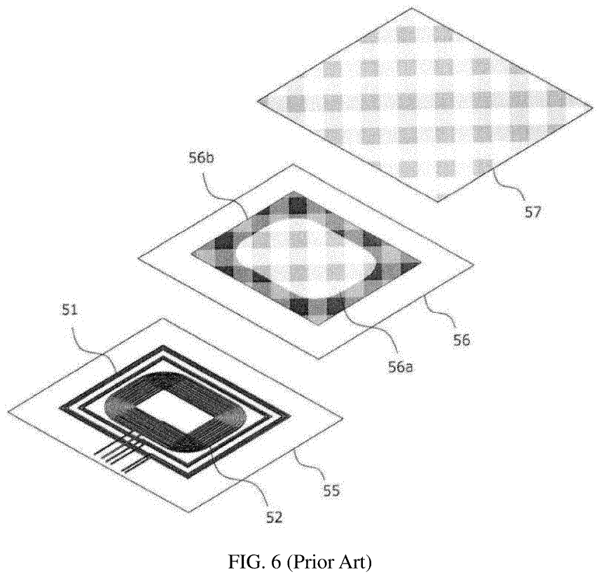

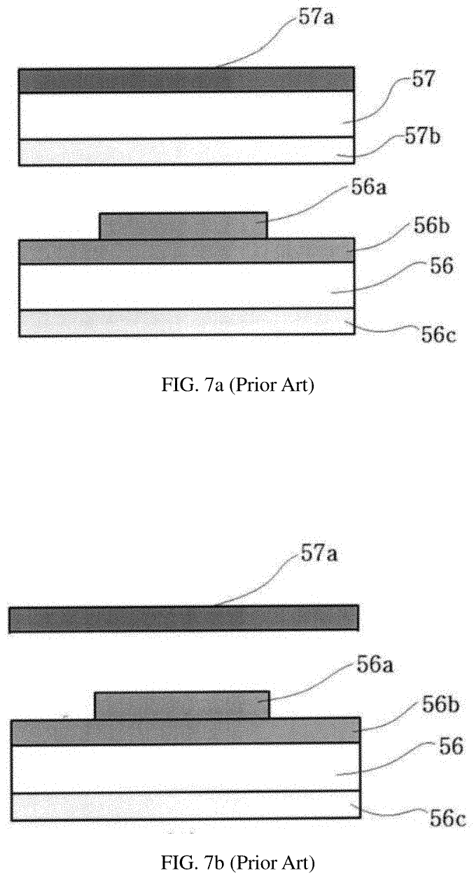

The following is a description of the reference numerals.

1: Metal thin film

F: Flexible thin film

M1: Surface metal layer

M2: Inner surface metal layer

M3: Two-sided metal layer

B10: Heat dissipation patch

B20: Heat dissipation radiation patch

B21: One side metal region

B22: The other side metal region

S1: One-way open slit

S2: Expansion slot

H: Spiral type antenna

H10: Inner spiral type pattern

H11: Inner start end

H12: Inner tail end

H20: Outer spiral type pattern

H21: Outer start end

H22: Outer tail end

V1: Via hole

V2: Via groove

T10: First terminal

T11: First outward terminal

T12: Via terminal

T20: Second terminal

T21: Second outward terminal

### DETAILED DESCRIPTION

Referring to the figures, there may be several preferred embodiments of a manufacturing method of a wireless communication antenna of the present disclosure as the embodiments thereof, and through such the embodiments, the purpose, features and advantages of the present disclosure may be better understood.

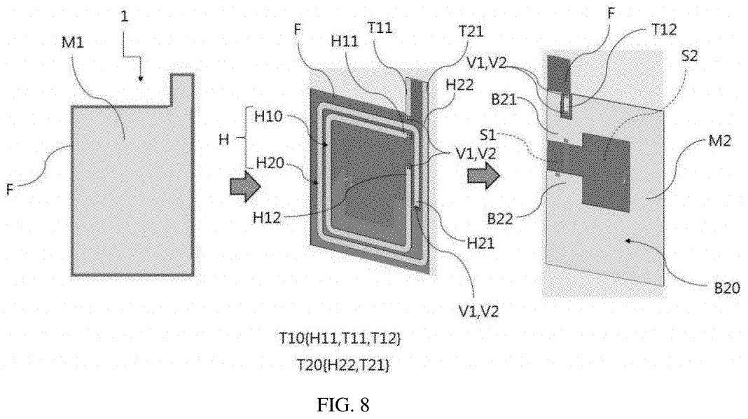

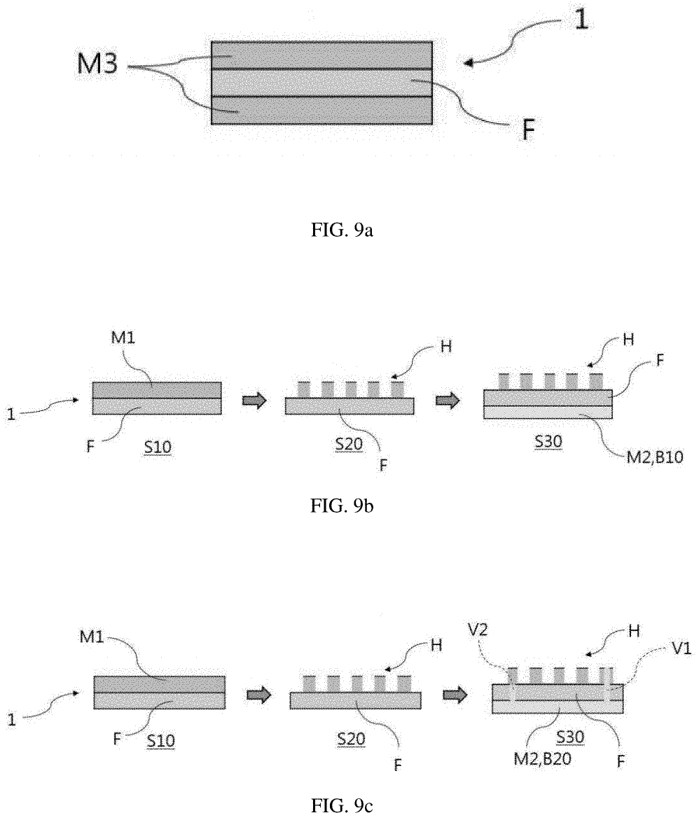

FIG. 8 is a process diagram showing a manufacturing method of a wireless communication antenna of the present disclosure, FIG. 9a is a cross-section diagram showing a metal thin film, FIG. 9b is a cross-section diagram for illustrating respective steps of a manufacturing method of a wireless communication antenna according to a first embodiment of the present disclosure, and FIG. 9c is a cross-section diagram for illustrating respective steps of a manufacturing method of a wireless communication antenna according to a second embodiment of the present disclosure. In the following description, the surface and the inner surface are distinguished in mutual names, and of course they can be interchanged.

As shown in FIG. 8 and FIGS. 9a-9c, in the manufacturing method of a wireless communication antenna of the present disclosure, after forming a surface metal layer M1 on one side surface of a flexible thin film F (S10), the surface metal layer M1 is patterned, and after forming a spiral type antenna H (S20), an inner surface metal layer M2 is formed on the other side surface of the flexible thin film F through metal vacuum deposition.

While manufacturing the wireless communication antenna, as shown in FIG. 9a, while forming a two-sided metal layer M3 on both surfaces of the flexible thin film F, since the metal wasted by etching is relatively a lot, and an etching process is complex, the productivity must be reduced significantly.

Considering the above problem, in the present disclosure, as shown in FIG. 8, FIG. 9b and FIG. 9c, in order to prepare a spiral type antenna H having impedance and resistance in accordance with the wireless communication antenna, a surface metal layer M1 preformed on one side surface of a flexible thin film F is used, and in order to implement an additional function of a so-called heat dissipation patch B10 or heat dissipation radiation patch B20, an inner surface metal layer M2 on the other side surface of the flexible thin film F is formed, and the inner surface metal layer M2 is simply and easily formed through a manner of vacuum deposition, which reduce the metal wasted during the processing, ensure an easy workability, and can improve productivity of the wireless communication antenna greatly.

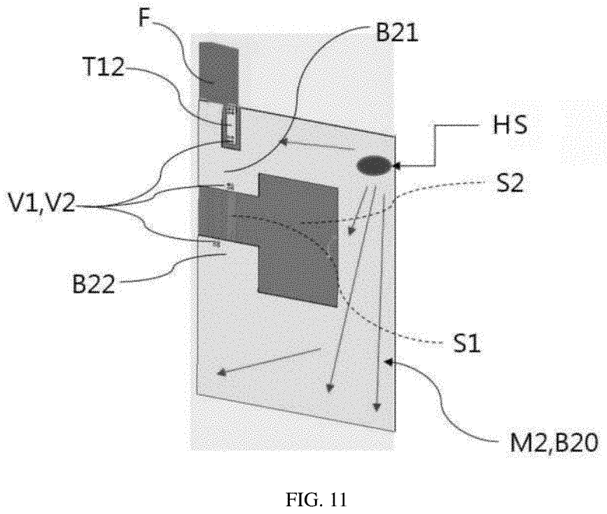

According to a first embodiment of the present disclosure, the inner surface metal layer M2 in the step S30 as shown in FIG. 9b is used for the heat dissipation patch B10 that can dissipate heat generated by various components in a portable terminal (the portion pointed by HS in FIG. 11), and the overall lightness, thinness, shortness and minimization of the tablet computer or smart phone can be realized (the heat dissipation/radiation metal layer B10 may apply one of gold, silver, copper, graphite, graphene and carbon with low resistance and good electrical conductivity to maximize radiation and heat dissipation) even if the structure of laminated heat dissipation thin films coated with a heat dissipation layer in the prior art document is not used.

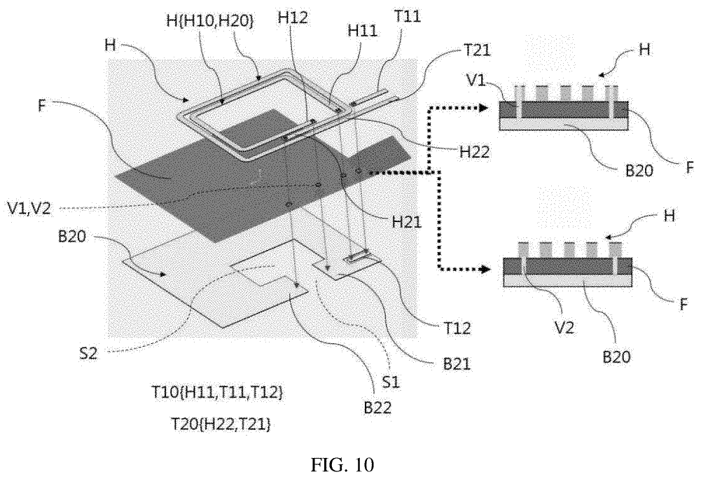

FIG. 10 is a exploded stereo diagram showing a wireless communication antenna according to a second embodiment of the present disclosure; and FIG. 11 is stereo diagram of a wireless communication antenna according to the second embodiment of the present disclosure viewed from the back.

According to the second embodiment of the present disclosure, as shown in FIG. 9c, FIG. 10 and FIG. 11, in the step S30, when the metal is vacuum deposited on the other side surface of the flexible thin film F, an one-way open slit S1 constituted in a one-way open type is formed. The inner surface metal layer M2 is divided into one side metal region B21 and the other side metal region B22 based on the one-way open slit S 1, so that the inner surface metal layer M2 is used as the heat dissipation radiation patch B20. Preferably, in the step S30, while vacuum depositing the metal on the other side surface of the flexible thin film F, an expansion slot S2 connected to the one-way open slit S1 is further formed.

Furthermore, in the step S20, the spiral type antenna H may include: an inner spiral type pattern H10 having an inner start end H11 and an inner tail end H12 formed by performing spiral type patterning on the surface metal layer M1 of one side surface of the flexible thin film F; and an outer spiral type pattern H20 having an outer start end H21 and an outer tail end H22 formed by performing spiral type patterning on the surface metal layer M1 of one side surface of the flexible thin film F at the outline of the inner spiral type pattern H10.

In the step S30, while vacuum depositing the metal on the other side surface of the flexible thin film F, the inner tail end H12 and the one side metal region B21, as well as the outer start end H21 and the other side metal region B22 are respectively connected up and down, so that the inner spiral type pattern H10, the heat dissipation radiation patch B20 and the outer spiral type pattern H20 are connected in sequence to be a spiral type.

At this time, in the step S30, as shown in FIG. 10, the flexible thin film F is placed between the inner tail end H12 and the one side metal region B21, and between the outer start end H21 and the other side metal region B22, a plurality of via holes V1 penetrating flexible thin film F in the middle vertically are formed, and the metal vacuum deposited on the other side surface of the flexible thin film F fills the plurality of via holes V1 to realize the connection between the inner tail end H12 and the one side metal region B21, and between the outer start end H21 and the other side metal region B22, A plating process independently performed on the via holes V1 is omitted to ensure the productivity.

Furthermore, in the step S30, as shown in FIG. 10, between the inner tail end H12 and the one side metal region B21, and between the outer start end H21 and the other side metal region B22, a plurality of via grooves V2 are formed through a manner of removing parts of the flexible thin film F, and the via grooves V2 expose the inner start end H12 and the outer start end H21 along the lower side direction, the metal is vacuum deposited on the other side surface of the flexible thin film F, and the metal fills the via grooves V2 to realize the connection between the inner tail end H12 and the one side metal region B21, and between the outer start end H21 and the other side metal region B22, and the usual process of independently plating the via grooves V2 may be omitted to ensure the productivity.

More specifically speaking, in the step S20 of the manufacturing method of the wireless communication antenna of the present disclosure, the inner spiral pattern H10 and the outer spiral type pattern H20 form a spiral type antenna H. The inner spiral type pattern H10 includes the inner start end H11 and the inner tail end H12 formed by performing spiral type patterning (etching) or numerical control work (NC work) on the surface metal layer M1 (e.g., a layer of metal layer constituted by a copper foil) of one side surface of the flexible thin film F constituted by a polyimide thin film and the like. The outer spiral type pattern H20 includes the outer start end H21 and the outer tail end H22 formed by performing spiral type patterning on the surface metal layer M1 of one side surface of the flexible thin film F at the peripheral of the inner spiral pattern H10.

In the step S30, while vacuum depositing the metal on the other side surface of the flexible thin film F, the inner tail end H11 and the one side metal region B21, and between the outer start end H21 and the other side metal region B22 are respectively connected up and down (in the step S30, the connection is implemented through the manner of filling the via holes V1 or via grooves V2 by the vacuum deposition of the metal), so that the inner spiral type pattern H10, the heat dissipation radiation patch B20 and the outer spiral type pattern H20 are connected in sequence to be a spiral type. Furthermore, the expansion slot S2 is further included, which is formed by expanding on the inner surface metal layer M2 while vacuum depositing the metal on the other side surface of the flexible thin film F, and is connected to the one-way open slit S1.

The inner spiral type pattern H10, the heat dissipation/radiation metal layer and the outer spiral type pattern H20 form the wireless communication antenna, such as an NFC, WPT, MST, or the like, in a manner of being connected in sequence to be a spiral type.

Especially, there are not only the inner spiral type pattern H10 and the outer spiral type pattern H20 at one side surface of the flexible thin film F as the spiral type antenna H, but also a spiral type wireless communication antenna that is wound through the number of the additional turns of the heat dissipation radiation patch B20 at the other side surface of the flexible thin film F is manufactured, so that communication performance in a narrow space in the portable terminal and space utilization of the portable terminal are ensured. Furthermore, since the one side metal region B21, the other side metal region B22, the inner spiral type pattern H10 and the outer spiral type pattern H20 formed by the one-way open slit S1 at the other side surface of the flexible thin film F are connected to each other, the heat dissipation radiation pattern works as a radiating body, which as the heat dissipation radiation patch B20 dissipates the heat generated by various components in the portable terminal while further maximizing the performance of near field wireless communication, so that the overall lightness, thinness, shortness and minimization of the tablet computer or smart phone can be realized (dissipation radiation patch B20 may apply one of gold, silver, copper, graphite, graphene and carbon with low resistance and good electrical conductivity to maximize radiation and heat dissipation) even if an additional structure of laminated heat dissipation thin films is not used.

As the wireless communication antenna, it may be, for example, a Near Field Communication (NFC), Wireless Power Transfer (WPT), Magnetic Secure Transmission (MST), mobile settlement service communication antenna or the like. Specifically speaking, the NFC, as one kind of radio frequency identification (RFID), is a non-contact wireless communication module using a frequency band of about 13.56 MHz, the WPT causes the current to flow through a wireless emission charging pad to form a magnetic field according to an electromagnetic induction principle, i.e., a principle of induced magnetic field, and by putting the smart phone thereon, it may charge a battery in a low frequency band, i.e., 100-200 KHz frequency band or 6 MHz frequency band, and the MST is used in a near field of 10-200 cm, and enable external terminals to transmit data to each other by using a non-contact magnetic inductive coupling force of the 13.56 MHz frequency band.

For example, the wireless communication antenna reflecting wireless charging of a battery in a portable is mounted, in most cases, near a metal (battery) or near a plurality of electronic components thereon. The metal or electronic components hinder the wireless communication antenna from obtaining an inductance current, i.e., if the wireless communication antenna is mounted near a metal, it causes a large number of phenomena of wireless communication hindering, this is because the metal reduces the inductance of the wireless communication antenna, thus, the Q-factor is reduced, so that there is a change in magnetic induction, and thereby the magnetic field causes the occurring of an eddy current inside the metal. Such an eddy current generates a magnetic field in an opposite direction according to the Len's law, which becomes a big problem in a near field wireless charging system.

For example, if the wireless communication antenna is placed near the surface of the metal (battery), the performance of the wireless communication antenna is rapidly reduced.

This is because a ground plane of the metal just at the bottom of the magnetic field or the electric field greatly reduces intensity of these electromagnetic fields, i.e., intensity of signals. Thus, it hinders the charging efficiency or the NFC function of the wireless communication antenna.

According to the above problem, for the one-way open slit S1 and the expanded slot S2 formed by performing patterning on the inner surface metal layer on the other side of the flexible film F applied in the present disclosure, it may guarantee paths of a magnetic field occurring due to currents of a near field transmitter (not shown in the figures) relatively more, so that the wireless communication antenna of a portable terminal is connected omni-directionally to form an induced current, which may, for example, charge a battery more efficiently, or further improve the NFC or MST function to guarantee near field wireless communication quality. Moreover, this function is not limited by a shape of the one-way open slit S1 or the expanded slot S2.

According to such a formation, the wireless communication antenna enables the magnetic field occurring when the current flows through the near field transmitter to be connected with the wireless communication antenna of the portable terminal through the expanded slot S2 and the one-way open slit S1 to be capable of charging a battery while forming the inductance current, or be capable of performing near field wireless communication, such as NFC or MST.

For example, when comparing the insertion loss between the wireless communication antenna having a structure of the expanded slot S2 or the one-way open slit S1 in the heat dissipating/radiating metal layer B20 and a near filed transmitter, and the insertion loss between the wireless communication antenna not having any one of structures of the expanded slot S2 and the one-way open slit S1 in the heat dissipating/radiating metal layer B20 and a near filed transmitter, one will find that when the heat dissipating/radiating metal layer B10 has the expanded slot S2 or the one-way open slit S1, the insertion loss is good (−10 dB), however, when the heat dissipating/radiating metal layer B20 does not have any one of the expanded slot S2 and the one-way open slit S1, the insertion loss is significantly reduced to be −60 to −50 dB, which cannot implement the function as a wireless communication antenna.

As a result, in the present disclosure, the spiral type wireless communication is formed by connecting the inner spiral pattern H10, the heat dissipation/radiation metal layer B10 and the outer spiral pattern H20 in sequence that are formed by using the surface metal layer M1 of the one side surface and the inner surface metal layer M2 of the other side surface of the thin and soft flexible thin film. That is, not only the inner spiral type pattern H10 and the outer spiral type pattern H20 of the surface of the flexible thin film F are formed, but also the spiral type wireless communication antenna that is wound through the number of the additional turns of the heat dissipation/radiation metal layer B20 of the other side surface of the flexible thin film F is further formed, so that the performance of the near field communication can be further maximized while making the heat dissipation/radiation metal layer B20 as the radiating body, and moreover, as the heat dissipation/radiation metal layer B20, it dissipates the heat generated by various components in the portable terminal, which may realize high-quality communication, ensuring heat dissipation, and lightness, thinness, shortness and minimization of the portable terminal.

Moreover, the patterning on the surface metal layer M1 of the one side surface of the flexible thin film F may form a plurality of spiral types, to form a plurality of wireless communication antennas such as NFC, WPT, MST and the like together.

On the other hand, the inner start end H11 of the inner spiral type pattern H10 is used as a first terminal T10, and the outer tail end H22 of the outer spiral type pattern H20 is used as a second terminal T20, such that it is for example, possible that a positive power source is supplied through the first terminal T10, and the negative power source is supplied through the second terminal T20.

More specifically speaking, the first terminal T10 may include: a first outward terminal T11 formed by performing outward and linear patterning on the metal layer on the one side surface of the flexible thin film F; an via terminal T12 formed by performing independent patterning on the heat dissipation/radiation metal layer B10 on the other side surface of the flexible thin film F; and a plurality of via holes V respectively connecting the inner start end H11 and the via terminal T12, as well as the via terminal T12 and the first outward terminal T11 up and down, so that the inner start end H11, the via terminal T12 and the first outward terminal T11 are connected in sequence. In this way, the inner start end H11, the via terminal T12 and the first outward terminal T11 are connected in sequence through the plurality of via holes V, thereby ensuring the number of turns of the inner spiral type pattern H10.

Furthermore, it is implemented by connecting the second terminal T20 to the second outward terminal T21 formed by performing outward and linear patterning on the surface metal layer on the one side of the flexible thin film F, so that, for example, the negative power source supply can be easily received.

What is claimed is:

1. A manufacturing method of a wireless communication antenna, comprising:
step S10, forming a surface metal layer on one side surface of a flexible thin film;
step S20, patterning the surface metal layer to form a spiral type antenna; and
step S30, vacuum depositing a metal on the other side surface of the flexible thin film to form an inner surface metal layer.

2. The manufacturing method of the wireless communication antenna of claim 1, wherein the inner surface metal layer of the step S30 is used as a heat dissipation patch.

3. The manufacturing method of the wireless communication antenna of claim 1, wherein, in the step S30, an one-way open slit unidirectionally opened is formed when depositing the metal on the other side surface of the flexible thin film in vacuum, such that the inner surface metal layer is divided into one side metal region and the other side metal region based on the one-way open slit, thereby the surface metal layer is used as a heat dissipation radiation patch.

4. The manufacturing method of the wireless communication antenna of claim 3, wherein the step S30 further comprises forming an expansion slot connected to the one-way open slit when vacuum depositing the metal on the other side surface of the flexible thin film.

5. The manufacturing method of the wireless communication antenna of claim 4, wherein, in the step S20, the spiral type antenna comprises: an inner spiral type pattern having an inner start end and an inner tail end formed by performing spiral type patterning on the surface metal layer of the one side surface of the flexible thin film; and an outer spiral type pattern having an outer start end and an outer tail end formed by performing spiral type patterning on the surface metal layer on the one surface of the flexible thin film at the peripheral of the inner spiral type pattern, and
wherein, in the step S30, the inner tail end and the one side metal region, and the outer start end and the other side metal region are respectively connected up and down when vacuum depositing the metal on the other side surface of the flexible thin film, so that the inner spiral type pattern, the heat dissipation radiation patch and the outer spiral type pattern are spirally connected in sequence.

6. The manufacturing method of the wireless communication antenna of claim 5, wherein, in the step S30, in a state that a plurality of via holes penetrate vertically flexible thin film in the middle, the metal is deposited on the other side surface of the flexible thin film in vacuum, such that the metal fills the plurality of via holes to realize the connection between the inner tail end and the one side metal region, and between the outer start end and the other side metal region.

7. The manufacturing method of the wireless communication antenna of claim 5, wherein, in the step S30, a plurality of via grooves are formed by removing parts of the flexible thin film, the via grooves expose the inner tail end and the outer start end toward a downside direction, and the metal is deposited on the other side surface of the flexible thin film in vacuum, such that the metal fills the via grooves to realize the connection between the inner tail end and the one side metal region, and between the outer start end and the other side metal region.

8. The manufacturing method of the wireless communication antenna of claim 5, wherein the inner start end is used as a first terminal, and
wherein the outer tail end is used as a second terminal.

9. The manufacturing method of the wireless communication antenna of claim 8, wherein the first terminal comprises:
a first outward terminal formed by performing linear patterning on the surface metal layer of the one side surface of the flexible thin film;
a via terminal formed in a manner of independently performing vacuum deposition on the inner surface metal layer of the other side surface of the flexible thin film; and
a plurality of via holes respectively connecting the inner start end and the via terminal, and the via terminal and the first outward terminal up and down, so that the inner start end, the via terminal and the first outward terminal are connected in sequence.

10. The manufacturing method of the wireless communication antenna of claim 8, wherein the second terminal is implemented by continuously connecting the surface metal layer on the one surface of the flexible thin film to the second outward terminal formed by outward and linear patterning.
